(19) United States
(12) Patent Application Publication
(10) Pub. No.: US 2012/0285819 A1
(43) Pub. Date: Nov. 15, 2012

(54) Combinatorial and Full Substrate Sputter Deposition Tool and Method

(75) Inventors: Kent Riley Child, Dublin, CA (US); Hong Sheng Yang, Pleasanton, CA (US); Rajesh Kelekar, Los Altos, CA (US)

(73) Assignee: Intermolecular, Inc., San Jose, CA (US)

(21) Appl. No.: 13/103,951

(22) Filed: May 9, 2011

(51) Int. Cl. C23C 14/34

(52) U.S. Cl. 204/192.12; 204/298.02; 204/298.15

(57) ABSTRACT

A dual purpose processing chamber is provided. The dual purpose processing chamber includes a lid disposed over a top surface of a processing region of the processing chamber. A plurality of sputter guns with a target affixed to one end of each of the sputter guns is included. The plurality of sputter guns extend through the lid of the process chamber, wherein each of the plurality of sputter guns is oriented such that a surface of the target affixed to each gun is angled toward an outer periphery of a substrate. In another embodiment, each of the sputter guns is affixed to an extension arm and the extension arm is configured to enable movement in four degrees of freedom. A method of performing a deposition process is also included.

### TECHNICAL FIELD

The present disclosure generally relates to the field of thin film deposition apparatus and method and more particularly to sputter deposition apparatus and methods used for both combinatorial and full substrate deposition.

### BACKGROUND

Physical vapor deposition is commonly used within the semiconductor industry, as well as within solar, glass coating, and other industries, in order to deposit a layer over a substrate. Sputtering is a common physical vapor deposition method, where atoms or molecules are ejected from a target material by high-energy particle bombardment and then deposited onto the substrate.

In order to identify different materials, evaluate different unit process conditions or parameters, or evaluate different sequencing and integration of processes, and combinations thereof, it may be desirable to be able to process different regions of the substrate differently. This capability, hereinafter called “combinatorial processing”, is generally not available with tools that are designed specifically for conventional full substrate processing. Furthermore, it may be desirable to subject localized regions of the substrate to different processing conditions (e.g. localized deposition) in one step of a sequence followed by subjecting the full substrate to a similar processing condition (e.g. full substrate deposition) in another step.

Conventional full substrate deposition processes and localized region based deposition processes, are currently performed in two different process tools. Accordingly, when it is desired to perform a sequence of steps that incorporates localized and full substrate deposition, the substrate must be moved between processing tools. This movement is costly in terms of throughput and may expose the substrate to an external environment.

Current full-substrate PVD tools used in semiconductor industry utilize a large sputter gun and large target, i.e., the target is larger than a wafer for uniform film deposition on the wafer, even for wafers as large as 300 mm. Alternatively, some full substrate PVD tools use a smaller sputter gun, e.g., 4″ diameter, with a rotating wafer, where the wafer may be 200 mm diameter or smaller and the sputter gun is pointed to the mid-radius of the wafer and the target-to-wafer spacing is relatively large, e.g., 200 mm.

What is needed is the use of smaller guns for uniform deposition on a larger substrate, e.g., 300 mm diameter wafer, and the capability of doing both conventional and combinatorial processing, either sputtering or co-sputtering, on the same tool. The use of smaller sputter guns allows the flexibility of having multiple sputter guns in the same PVD chamber of limited size. A much smaller footprint sputter chamber can easily be integrated into a cluster platform.

It is within this context that the current embodiments arise.

### SUMMARY

Embodiments of the present invention provide a sputter processing tool that is capable of both full substrate and combinatorial processing of the substrate. Several inventive embodiments of the present invention are described below.

In one aspect of the invention, a dual purpose processing chamber is provided. The dual purpose processing chamber includes a lid disposed over a top surface of a processing region of the processing chamber. A plurality of sputter guns with a target affixed to one end of each of the sputter guns is included. The plurality of sputter guns extend through the lid of the process chamber, wherein each of the plurality of sputter guns is oriented such that a surface of the target affixed to each sputter gun is angled toward an outer periphery of the substrate. In another embodiment, each of the sputter guns is affixed to an extension arm and the extension arm is configured to enable movement in four degrees of freedom.

In another aspect of the invention a method of processing a substrate is provided. The method includes depositing a layer of material over an entirety of a surface of a substrate through multiple sputter guns disposed either above or below the surface of the substrate and combinatorially depositing another layer of material over a region of the layer of material through the multiple sputter guns. In one embodiment, the full-substrate deposition and combinatorial deposition are performed sequentially in the same processing chamber. In another embodiment, the multiple sputter guns are each oriented such that a target surface of each sputter gun is angled toward an outer periphery of the substrate.

Other aspects of the invention will become apparent from the following detailed description, taken in conjunction with the accompanying drawings, illustrating by way of example the principles of the invention.

### BRIEF DESCRIPTION OF THE DRAWINGS

The present invention will be readily understood by the following detailed description in conjunction with the accompanying drawings. Like reference numerals designate like structural elements.

FIG. 1 is a simplified schematic diagram illustrating a dual purpose processing chamber configured to combinatorially process a substrate and/or deposit a layer of material over an entirety of the substrate in accordance with one embodiment of the invention.

FIG. 2 is a simplified schematic diagram illustrating another view of a dual purpose deposition processing chamber in accordance with one embodiment of the invention.

FIG. 3 is a simplified schematic diagram illustrating a sputter gun coupled to an arm having multiple degrees of freedom of movement in accordance with one embodiment of the invention.

FIG. 4A is a simplified schematic diagram illustrating a partial perspective view of a lid having integrated gun shields in accordance with one embodiment of the invention.

FIG. 4B is a simplified schematic diagram illustrating a partial perspective bottom view of a lid having integrated gun shields in accordance with one embodiment of the invention.

FIG. 5A is a simplified schematic diagram illustrating a cross-sectional view of a processing chamber capable of performing combinatorial and full substrate deposition techniques in accordance with one embodiment of the invention.

FIG. 5B is a simplified schematic diagram illustrating a perspective view of a lid and process kit shield for a dual purpose process chamber in accordance with one embodiment of the invention.

FIG. 6 is a simplified schematic diagram illustrating a cross sectional view of the process kit shield and the lid of the dual purpose processing chamber in accordance with one embodiment of the invention.

FIG. 7A is a simplified schematic diagram of the lid having integrated gun shields for a dual purpose processing chamber in accordance with one embodiment of the invention.

FIG. 7B is a simplified schematic diagram illustrating a cross sectional view of the gun shields in accordance with one embodiment of the invention.

FIG. 8 is a simplified schematic diagram of a door shield and door arm for the process kit shield in accordance with one embodiment of the invention.

FIG. 9 is a simplified schematic diagram illustrating an integrated high productivity combinatorial (HPC®) system in accordance with one embodiment of the invention.

### DETAILED DESCRIPTION

The embodiments described herein provide a method and apparatus related to sputter deposition processing. It will be obvious, however, to one skilled in the art, that the present invention may be practiced without some or all of these specific details. In other instances, well known process operations have not been described in detail in order not to unnecessarily obscure the present invention.

In addition to depositing a layer of material over an entire substrate, the embodiments described below provide details for a multi-region processing system and associated sputter guns that enable processing a substrate in a combinatorial fashion. Thus, different regions of the substrate may have different properties, which may be due to variations of the materials, unit process conditions or parameters, and process sequences, etc. Within each region the conditions are preferably substantially uniform so as to mimic conventional full wafer processing, however, valid results can be obtained for certain experiments without this requirement. In one embodiment, the different regions are isolated so that there is no interaction between the different regions.

It should be appreciated that the combinatorial processing of the substrate may be combined with conventional processing techniques where substantially the entire substrate is uniformly processed, e.g., subjected to the same materials, unit processes and process sequences. Thus, the embodiments described herein can perform combinatorial deposition processing and conventional full substrate processing in the same chamber. Consequently, in one substrate processed in the same chamber, information concerning the varied processes and the interaction of the varied processes with the conventional processes can be evaluated. Accordingly, a multitude of data is available from a single substrate for a desired process.

The embodiments described herein enable the application of combinatorial techniques to process sequence integration in order to arrive at a globally optimal sequence of thin film processing by considering interaction effects between the unit manufacturing operations, the process conditions used to effect such unit manufacturing operations, as well as materials characteristics of components utilized within the unit manufacturing operations. Rather than only considering a series of local optimums, i.e., where the best conditions and materials for each manufacturing unit operation is considered in isolation, the embodiments described below consider interactions introduced due to the multitude of processing operations that are performed and the order in which such multitude of processing operations are performed when fabricating a semiconductor device. A global optimum sequence order is therefore derived and as part of this derivation, the unit processes, unit process parameters and materials used in the unit process operations of the optimum sequence order are also considered.

The embodiments described further below analyze a portion or sub-set of the overall process sequence used to manufacture a semiconductor device or other products. Once the subset of the process sequence is identified for analysis, combinatorial process sequence integration testing is performed to optimize the materials, unit processes and process sequence used to build that portion of the device or structure. During the processing of some embodiments described herein, structures are formed on the processed semiconductor substrate that are equivalent to the structures formed during actual production of the semiconductor device. For example, such structures may include, but would not be limited to, trenches, vias, interconnect lines, capping layers, masking layers, diodes, memory elements, gate stacks, transistors, or any other series of layers or unit processes that create an intermediate structure found on semiconductor chips. While the combinatorial processing varies certain materials, unit processes, or process sequences, the composition or thickness of the layers or structures or the action of the unit process, such as cleaning, surface preparation, etch, deposition, planarization, implantation, surface treatment, etc., is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (intra-region uniformity) and between regions (inter-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameters, e.g., materials, unit processes, unit process parameters, or process sequences, and not the lack of process uniformity.

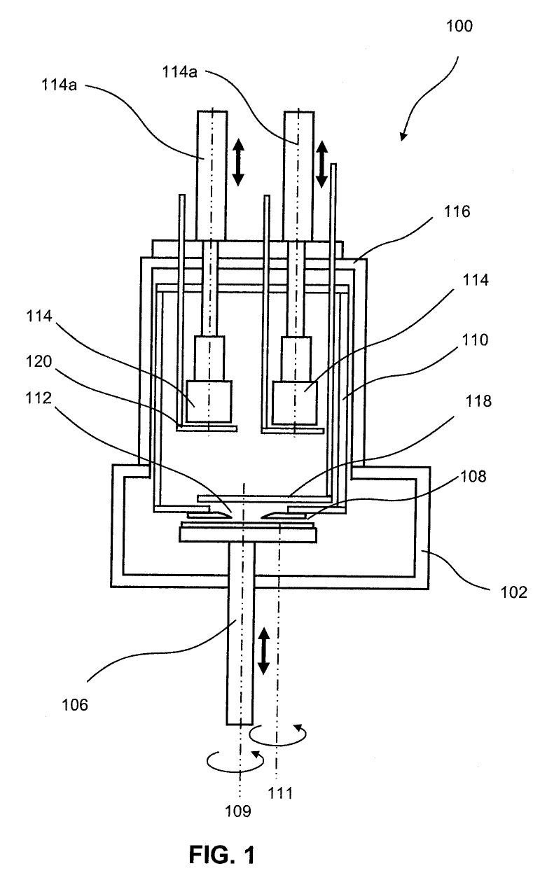

FIG. 1 is a simplified schematic diagram illustrating a dual purpose processing chamber configured to perform combinatorial processing and full substrate processing in accordance with one embodiment of the invention. Processing chamber 100 includes a bottom chamber portion 102 disposed under top chamber portion 116. Within bottom portion 102 substrate support 106 is configured to hold a substrate 108 disposed thereon and can be any known substrate support, including but not limited to a vacuum chuck, electrostatic chuck or other known mechanisms. Substrate support 106 is capable of both rotating around its own central axis 109 (referred to as “rotation” axis), and rotating around an exterior axis 111 (referred to as “revolution” axis). Such dual rotary substrate support is central to combinatorial processing using site-isolated mechanism which will be explained later. In addition, substrate support 106 may move in a vertical direction. It should be appreciated that the rotation and movement in the vertical direction may be achieved through known drive mechanisms which include magnetic drives, linear drives, worm screws, lead screws, a differentially pumped rotary feed through drive, etc.

Substrate 108 may be a conventional round 200 mm, 300 mm, or any other larger or smaller substrate/wafer size. In other embodiments, substrate 108 may be a square, rectangular, or other shaped substrate. One skilled in the art will appreciate that substrate 108 may be a blanket substrate, a coupon (e.g., partial wafer), or even a patterned substrate having predefined regions. In another embodiment, substrate 108 may have regions defined through the processing described herein. The term region is used herein to refer to a localized area on a substrate which is, was, or is intended to be used for processing or formation of a selected material. The region can include one region and/or a series of regular or periodic regions predefined on the substrate. The region may have any convenient shape, e.g., circular, rectangular, elliptical, wedge-shaped, etc. In the semiconductor field a region may be, for example, a test structure, single die, multiple die, portion of a die, other defined portion of substrate, or an undefined area of a substrate, e.g., blanket substrate which is defined through the processing.

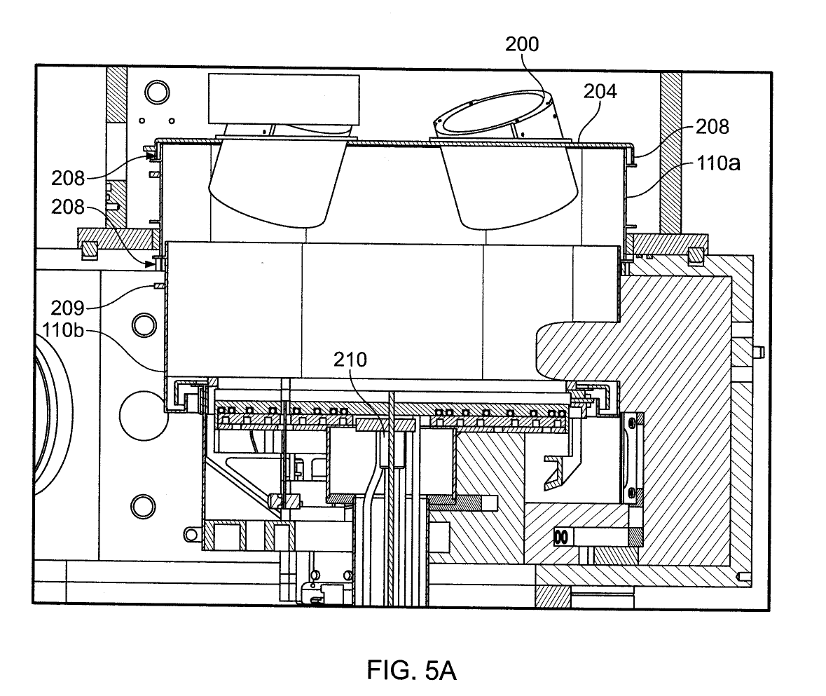

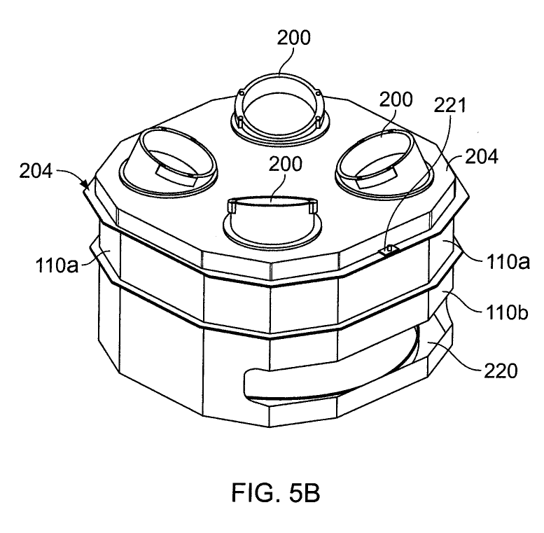

Top chamber portion 116 of chamber 100 in FIG. 1 includes process kit shield 110, which defines a confinement region over a radial portion of substrate 108. Process kit shield 110 is a sleeve having a base (optionally integrated with the shield) and an optional top within chamber 100 that may be used to confine a plasma generated therein. The generated plasma will dislodge atoms from a target and the sputtered atoms will deposit on an exposed surface of substrate 108 to combinatorially process regions of the substrate in one embodiment. In another embodiment, full wafer processing can be achieved through the multiple process guns 114 as described further below. Process kit shield 110 is capable of being moved in and out of chamber 100, i.e., the process kit shield is a replaceable insert. In another embodiment, process kit shield 110 remains in the chamber for both the full substrate and combinatorial processing. Process kit shield 110 includes an optional top portion, sidewalls and a base. In one embodiment, process kit shield 110 is configured in a cylindrical shape, however, the process kit shield may be any suitable shape and is not limited to a cylindrical shape. It should be noted that a process kit change may be made to convert full-substrate deposition configuration to combinatorial processing configuration, and vice versa. However, alternative embodiments can have an aperture shutter garage attached to the chamber so that full-substrate processing may be performed with the aperture shutter moved into the garage, i.e., nothing is covering the substrate. It should be appreciated that combinatorial processing may be performed with the aperture shutter moved to a position above the substrate. In another embodiment, the use of “shadow mask” may be incorporated where the “shadow mask” can be placed above the substrate through the slit valve opening 220 illustrated with reference to FIG. 5B.

The base of process kit shield 110 includes an aperture 112 through which a surface of substrate 108 is exposed for deposition or some other suitable semiconductor processing operations. Within top portion 116 is cover plate 118 which is moveably disposed over the base of process kit shield 110. Cover plate 118 may slide across a bottom surface of the base of process kit shield 110 in order to cover or expose aperture 112 in one embodiment. In another embodiment, cover plate 118 is controlled through an arm extension which moves the cover plate to expose or cover aperture 112 as will be described in more detail below. It should be noted that although a single aperture is illustrated, multiple apertures may be included. Each aperture may be associated with a dedicated cover plate or a cover plate can be configured to cover more than one aperture simultaneously or separately. Alternatively, aperture 112 may be a larger opening and plate 118 may extend with that opening to either completely cover the aperture or place one or more fixed apertures within that opening for processing the defined regions. The dual rotary substrate support 106 is central to the site-isolated mechanism, and it allows any location of the substrate or wafer to be placed under the aperture 112. Hence, the site-isolated deposition is possible at any location on the wafer/substrate. Using a dual rotary substrate support gives a much smaller footprint than a stage having X-Y translation and so the chamber can easily be integrated into a cluster platform.

A slide cover plate, or gun shutter, 120 may be included. Slide cover plate 120 functions to seal off a deposition gun when the deposition gun may not be used for the processing in one embodiment. For example, two process guns 114 are illustrated in FIG. 1. Process guns 114 are moveable in a vertical direction so that one or both of the guns may be lifted from the slots of the shield. While two process guns are illustrated, any number of process guns may be included, e.g., one, three, four or more process guns may be included. Where more than one process gun is included, the plurality of process guns may be referred to as a cluster of process guns. Slide cover plate 120 can be transitioned to isolate the lifted process guns from the processing area defined within process kit shield 110. In this manner, the process guns are isolated from certain processes when desired. It should be appreciated that slide cover plate 120 may be integrated with the top of the shield unit 110 to cover the opening as the process gun is lifted or individual cover plate 120 can be used for each target. In one embodiment, process guns 114 are oriented or angled so that a normal reference line extending from a planar surface of the target of the process gun is directed toward an outer periphery of the substrate being processed as illustrated in more detail below. The target/gun tilt angle depends on the target size, target-to-substrate spacing, target material, process power/pressure, etc.

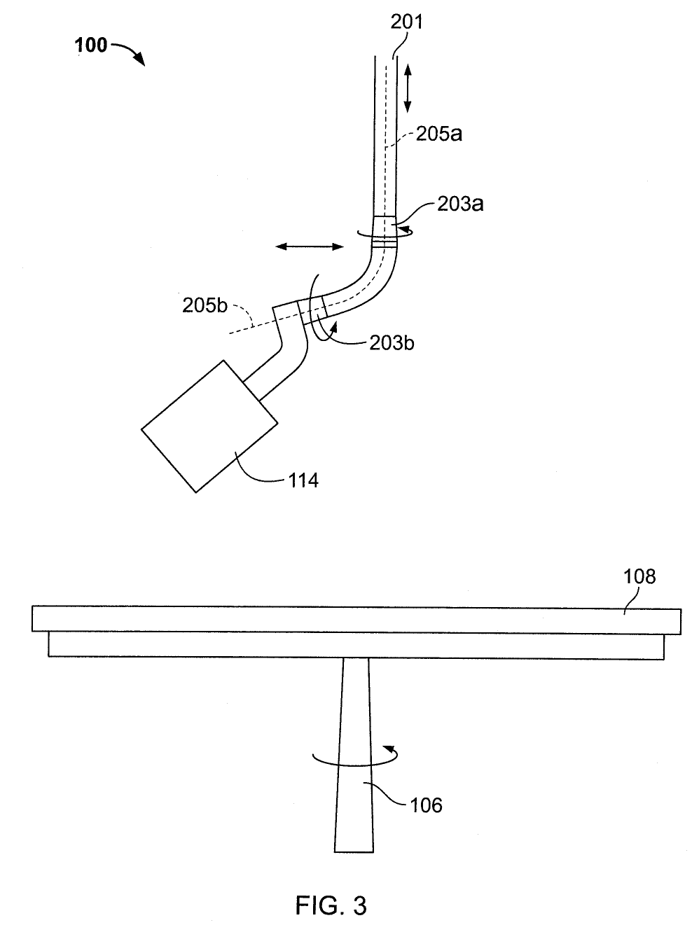

Top section 116 of chamber 100 of FIG. 1 includes sidewalls and a top plate which house process kit shield 110. Arm extensions 114a, which are fixed to process guns 114 may be attached to a suitable drive, e.g., lead screw, worm gear, etc., configured to vertically move process guns 114 toward or away from a top plate of top portion 116. Arm extensions 114a may be pivotally affixed to process guns 114 to enable the process guns to tilt relative to a vertical axis. In one embodiment, process guns 114 tilt toward aperture 112 when performing combinatorial processing and tilt toward a periphery of the substrate being processed when performing full substrate processing. It should be appreciated that process guns 114 may tilt away from aperture 112 when performing combinatorial processing in another embodiment. In yet another embodiment, arm extensions 114a are attached to a bellows that allows for the vertical movement and tilting of process guns 114. Arm extensions 114a enable movement with four degrees of freedom in one embodiment as described with reference to FIG. 3. Where process kit shield 110 is utilized, the openings are configured to accommodate the tilting of the process guns. In one embodiment, the axis of process gun, i.e., a normal to a planar surface of the target of the process guns, is tilted by ten degrees or less relative to the vertical axis of the substrate. In another embodiment, the process guns are tilted by ten degrees or more relative to the vertical axis. In this embodiment, the process guns may be tilted to an angle between ten and ninety degrees relative to the vertical axis. In another embodiment, the process guns are tilted between about one degree and seventy five degrees relative to the vertical axis. It should be appreciated that the gun may be tilted toward an aperture in the base plate to further enhance uniformity of a layer of material deposited through the aperture or tilted toward a periphery of the substrate to enhance uniformity of a layer deposited for full substrate processing. The amount of tilting of the process guns may be dependent on the process being performed in one embodiment. In one embodiment, a 100 angstrom TiN film was deposited on 300 mm wafer with resistivity non-uniformity of less than 3% (1 sigma) and thickness non-uniformity of less than 6% (1 sigma) by tilting the gun with 2″ diameter Ti target by ˜22 degrees towards the periphery of the 300 mm wafer, at a target-to-wafer spacing of 140 mm, a spacing of 145 mm between target center and chamber center axis, a process power of 300 W and a chamber pressure of 2 mT. While the embodiments illustrate two or four process guns it should be appreciated that any number of process guns may be utilized in the outward orientation to provide for both full substrate processing and combinatorial processing within the same chamber. In one embodiment, the angle of orientation, e.g., the angle between a normal to the bottom planar surface of the process gun and a normal to a surface of a substrate support of the process chamber, may be adjusted when different numbers of processing guns are employed. In another embodiment, the sputter gun may be disposed below the substrate as one skilled in the art would appreciate that the sputter gun must face the surface of the substrate and that the exemplary illustration of FIG. 1 is not meant to be limiting.

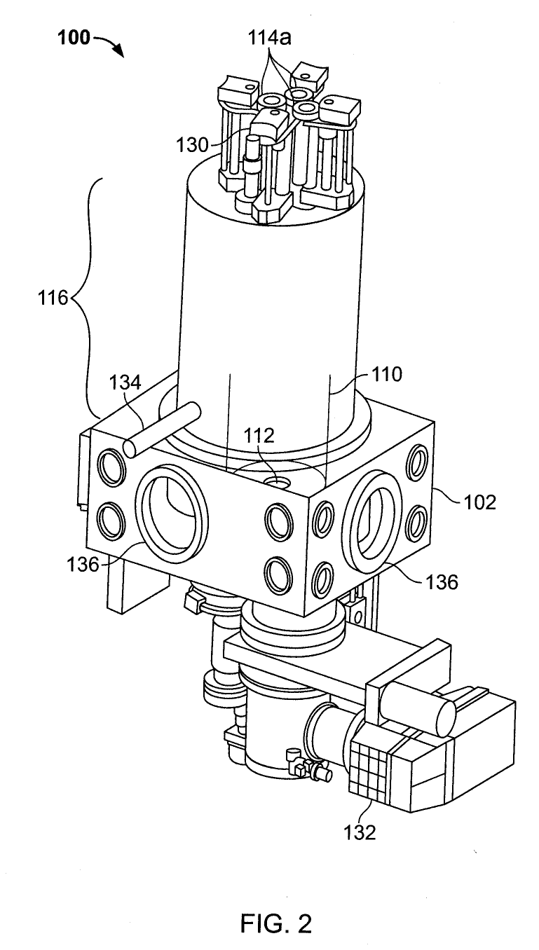

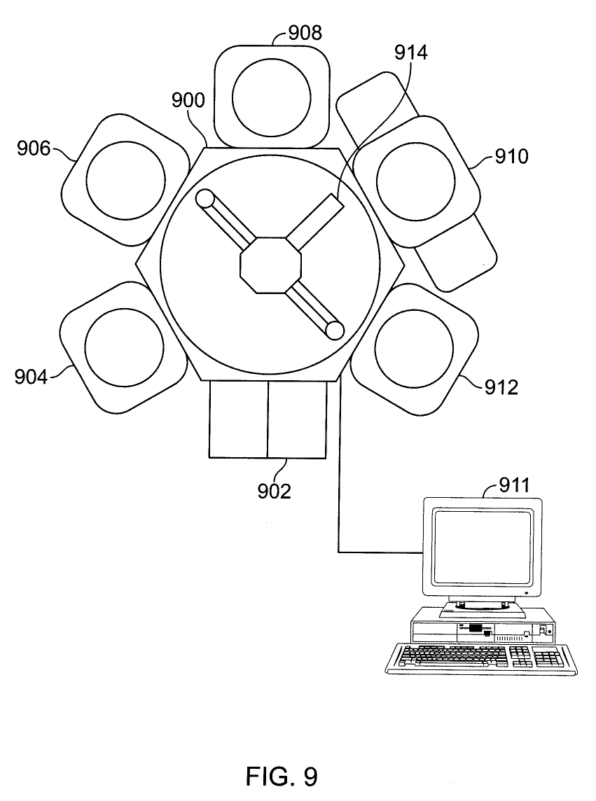

FIG. 2 is a simplified schematic diagram illustrating another view of a dual purpose processing chamber in accordance with one embodiment of the invention. Process chamber 100 includes bottom portion 102 disposed under top portion 116. The substrate support referred to in FIG. 1 is housed within bottom portion 102. Bottom portion 102 of FIG. 2 includes access ports 136 which may be utilized for access to the chamber for pulling a vacuum, or other process monitoring operations. In addition, bottom portion 102 includes slit valve 134 which enables access for a substrate to move into and out of bottom portion 102. In one embodiment, process tool 100 may be part of a cluster tool as described further with regard to FIG. 9. One skilled in the art will appreciate that a robot may be utilized to move substrates into and out of process chamber 100 through slit valve 134. In the embodiment described with regard to FIG. 2, process guns disposed within top portion 116 are attached to corresponding arm extensions 114a which protrude through a top surface of top portion 116, as shown in FIGS. 1 and 2. Also protruding through a top surface of top portion 116 is heat lamp 130 which is disposed within top portion 116 of chamber 100 and used for chamber bake-out.

Drive 132 of FIG. 2 may be used to provide the rotational means for rotating a substrate support disposed within bottom portion 102. In addition, drive 132 may provide the mechanical means for raising or lowering the substrate support. Within the embodiment described by FIG. 2, a rotation axis 109 of the substrate support and a revolution axis 111 of the substrate support are offset from each other in order to achieve a pattern of regions or an array of regions on the substrate as illustrated in more detail with regard to FIG. 9. In a case of a 300 mm diameter wafer being the substrate, the offset is half of the wafer radius. The processing defines regions on a substrate in one embodiment. In another embodiment, the regions are predefined and the processing guns provide further processing for the regions. The substrate is processed through aperture 112 located through the base of process kit shield 110 in this embodiment. As described above, process kit shield 110 will confine a plasma used for a physical vapor deposition (PVD). The array or cluster of deposition guns within top portion 116 enables co-sputtering of different materials onto a layer of a substrate, as well as a single material being deposited and various other processes. Accordingly, numerous combinations of target materials or multiple deposition guns having the same target material, or any combination thereof may be applied to the different regions so that an array of differently processed regions results for the combinatorial processing.

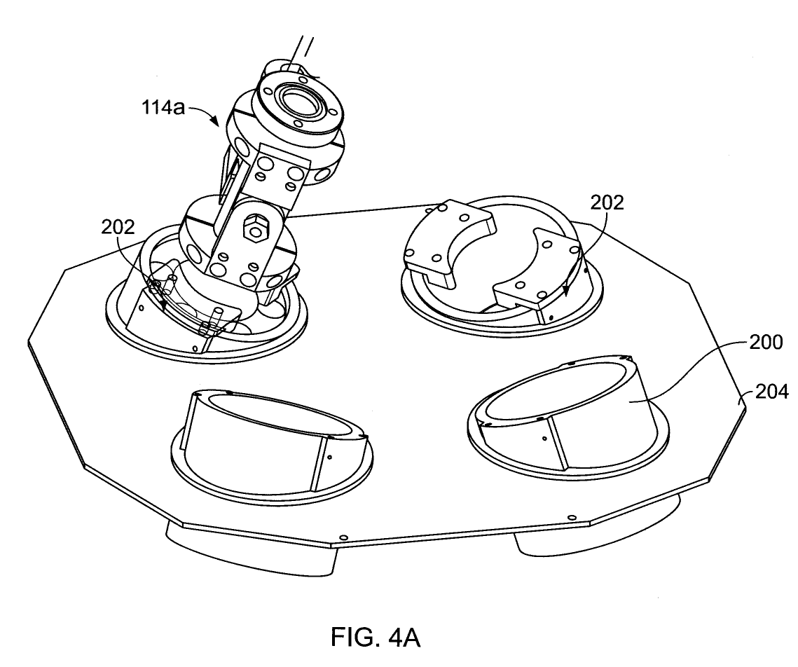

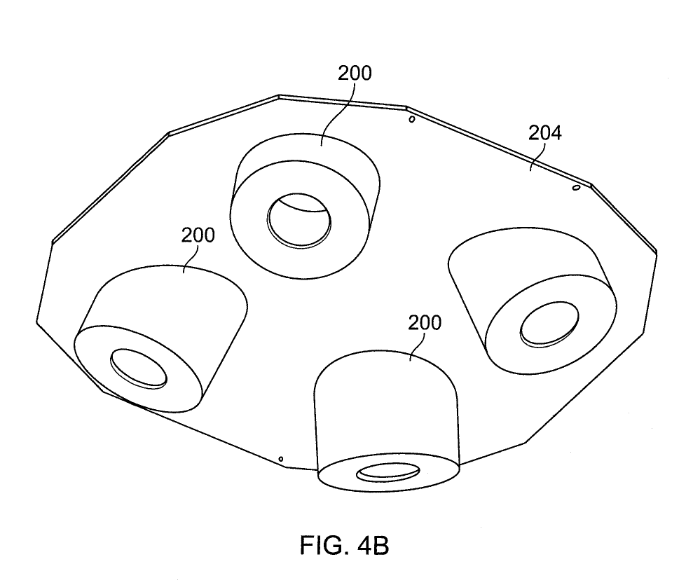

The chamber described with regards to FIGS. 1 and 2 may be incorporated into a cluster-tool in which conventional processing tools are included. Thus, the substrate may be conventionally processed (i.e., the whole wafer subject to one process or set of processes to provide uniform processing across the wafer) and placed into the combinatorial processing tool (or moved within the tool as described with respect to FIG. 4) illustrated herein in order to evaluate different processing techniques on a single substrate. In addition, process chamber 100 is a dual process chamber that may be utilized to perform both combinatorial and conventional deposition processes sequentially without having to transfer the substrate.

Furthermore, the embodiments described herein provide for a “long throw” chamber in which a distance from a top surface of a substrate being processed and the surface of a target on a deposition gun is greater than 100 mm. It should be noted that the target diameter for the process guns described herein is generally less than the diameter of the substrate being processed, as opposed to conventional processing guns utilized for full substrate processing where the target diameter is greater than the diameter of the substrate being processed in order to ensure uniform deposition over the entire surface of the substrate.

The substrate may have differently processed regions, where each region is substantially locally uniform in order to evaluate the variations enabled through the combinatorial processing. It should be noted that the depositions rate will decrease with the increase in target-to-substrate distance. This increase in distance would negatively impact throughput for a production tool and therefore is not usually considered for conventional processing tool. However, the resulting uniformity and multitude of data obtained from processing the single substrate combinatorially far outweighs any throughput impact due to the decrease in the deposition rate. It is noted that the chamber does not require long throw to be effective, but such an arrangement is a configuration that may be implemented.

FIG. 3 is a simplified schematic diagram illustrating a sputter gun coupled to an arm having multiple degrees of freedom of movement in accordance with one embodiment of the invention. Process gun 114 is illustrated as being coupled to arm 201. It should be appreciated that process gun 114 may be a magnetron gun in one embodiment. Arm 201 includes joints 203a and 203b. In one embodiment, joints 203a and 203b are magnetic liquid rotary seals, such as ferrofluidic seals. One skilled in the art will appreciate that the magnetic liquid rotary seal enables rotary motion while maintaining a hermetic seal through a physical barrier in the form of a ferrofluid. It should be appreciated that the utilities for process gun 114 are supplied through arm 201. In one embodiment, the utilities include power, cooling fluid, air, and any other necessary process requirements. Joints 203a and 203b are configured to provide rotation around axes 205a and 205b, respectively. Additionally, arm 201 may translate in a vertical and horizontal direction as indicated by the vertical and horizontal arrows within FIG. 3. Process gun 114 is disposed over substrate 108, which rests on substrate support 106. It should be appreciated that in one embodiment a surface of a target affixed to process gun 114 is angled toward an outer periphery of the substrate.

FIG. 4A is a simplified schematic diagram illustrating a partial perspective view of a lid having integrated gun shields in accordance with one embodiment of the invention. Lid 204 includes a plurality of openings through which gun ground shields 200 extend through. In the embodiment of FIG. 4A four openings are provided for four sputter guns. However, it should be appreciated that any number of openings and sputter guns, e.g., more or less than four, may be utilized with the embodiments described herein. Gun body retainers 202 extend inward from a periphery of one end of gun shields 200. Gun body retainers 202 secure a sputter gun placed within gun shields 200. In one embodiment, a threaded connection is provided to secure the sputter gun to gun body retainer 202. Arm extension 114a provides an interface between the process gun and the extension arm illustrated in FIG. 3. Lid 204 and gun shields 200 are composed of a conductive material, such as aluminum or stainless steel in order to provide a grounding pathway through lid 204 to chamber ground.

FIG. 4B is a simplified schematic diagram illustrating a partial perspective bottom view of a lid having integrated gun shields in accordance with one embodiment of the invention. Gun shields 200 extend through lid 204. Each of gun shields 200 includes an opening on a bottom surface of the gun shields in order to accommodate a target of the sputter gun when inserted into the gun shield. Gun shields 200 are oriented so that the front surface of the gun shields is directed or angled toward an outer periphery of the substrate. In one embodiment, gun shields 200 are welded to lid 204. In this embodiment the bottom surface of lid 204 appears as a single or unitary block from a viewpoint of a substrate being processed.

FIG. 5A is a simplified schematic diagram illustrating a cross-sectional view of a processing chamber capable of performing combinatorial and full substrate deposition techniques in accordance with one embodiment of the invention. Gun shields 200 extend through lid 204 into a processing region defined under the lid. A process kit shield is disposed between a bottom surface of lid 204 and a substrate support of the process chamber. The process kit shield includes an upper shield 110a disposed over a lower shield 110b. As illustrated in FIG. 5A, lid 204 includes an outer edge that is rounded and extends outward from a surface of the lid. An edge of the rounded portion of the outer periphery of lid 204 rests or contacts a side flange of upper shield 110a defined along an outer surface of shield 110a. Thus, the contact edge between lid 204 and upper shield 110a falls outside of the processing region. Consequently, any particles created from rubbing fall outward, rather than onto a substrate within the processing region. Likewise, upper shield 110a contacts lower shield 110b outside of the processing region. This staggered support structure is illustrated in regions 208. In one embodiment, grounding studs 209 are provided with the upper and lower shields for providing a grounding pathway to the lower body of the processing chamber.

Still referring to FIG. 5A, substrate support 106 is rotatable around a rotation axis 109 and a revolution axis 111 of the substrate support. In addition, the utilities for the substrate support 106 are provided though shaft 210 of the substrate support. It should be appreciated that ferrofluidic seals may be utilized with shaft 210. The utilities delivered through a central umbilical cord in shaft 210 can include power, fluids for heating and cooling the substrate support, etc. In this manner, continuous rotation of substrate support 106 during the deposition operations eliminates any tangling of cables and conduits proceeding into the pedestal of the substrate support.

FIG. 5B is a simplified schematic diagram illustrating a perspective view of a lid and process kit shield for a dual purpose process chamber in accordance with one embodiment of the invention. Lower shield 110b is illustrated having opening 220 which is covered by a door in one embodiment as illustrated with reference to FIG. 8. Upper shield 110a is disposed over lower shield 110b and rests on a side flange extending from the outer surface of the lower shield. Lid 204 is disposed over upper shield 110a and also rests on a side flange extending from the outer surface of the upper shield in this embodiment. In one embodiment, lower shield and upper shield are secured to each other through the side flanges. In another embodiment, lid 204 has tab 221 extending therefrom. In this embodiment, an opening within the tab accepts a pin extending from the side flange for alignment and/or attachment purposes. It should be appreciated that in one embodiment, lower shield 110b may be secured and grounded to a lower portion of the chamber body through holes in the side flange of the lower shield. The process kit shield and lid 204 may be utilized for combinatorial processing and may or may not be removed for conventional full substrate processing in one embodiment. In another embodiment, a cover plate may be inserted through opening 220 for combinatorial processing and removed for full substrate processing.

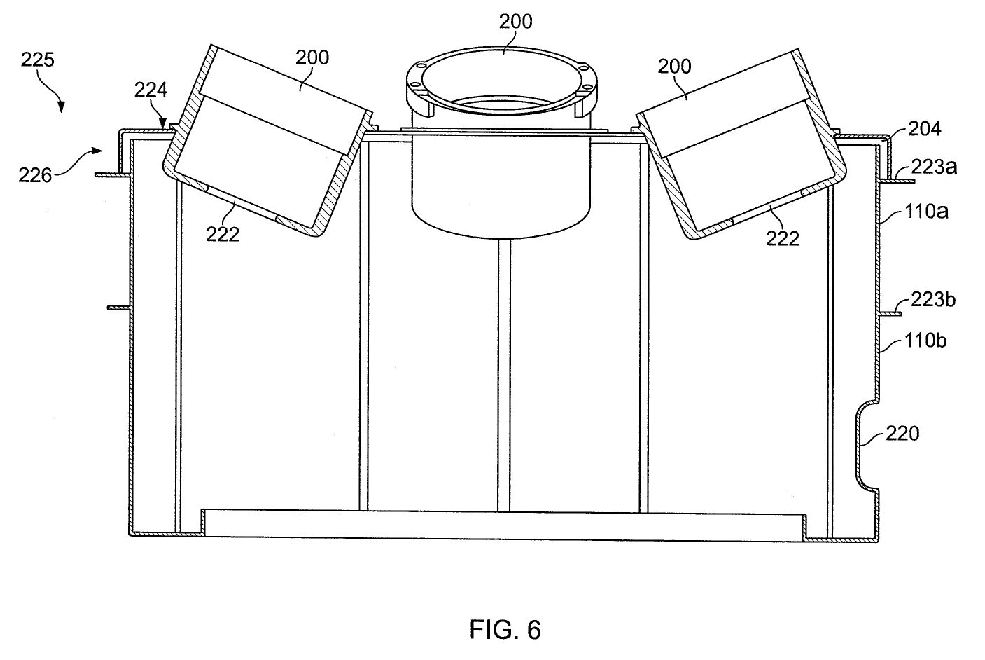

FIG. 6 is a simplified schematic diagram illustrating a cross sectional view of the process kit shield and the lid of the dual purpose processing chamber in accordance with one embodiment of the invention. The process kit shield includes lower shield 110b and upper shield 110a. Side flange 223b extends from lower shield 110b, while side flange 223a extends from upper shield 110a. Lid 204 is disposed over a top edge of upper shield 110a. Gun shields 200 are integrated into lid 204. In one embodiment, gun shields 200 are welded to lid 204 under flange 224 extending from the gun shields so that the bottom surface of the lid appears as a single continuous surface from a viewpoint of a substrate disposed within the processing region defined under lid 204. Targets 222 of the sputter guns are accommodated through an opening in the bottom surface of gun shields 200. Target 222 has a flange area which needs to be shielded by gun shield 200. The opening on gun shields 200 is provided for a stable plasma on the target surface. It should be appreciated that the target is pre-installed before the sputter gun is disposed onto the integrated gun shield 200. In addition, an outer edge 226 of the bottom surface of gun shield 200 is rounded and outside a line of sight from target 222 in order to prevent particulates from attaching to the outer edge and subsequently falling onto a surface of the substrate being processed. Gap 225 extends between an upper edge of upper shield 110a and a bottom surface of lid 204. In one embodiment, the surfaces may touch in order to eliminate gap 225. In addition, the upper edge of upper shield 110a is also out of a line of sight of target 222.

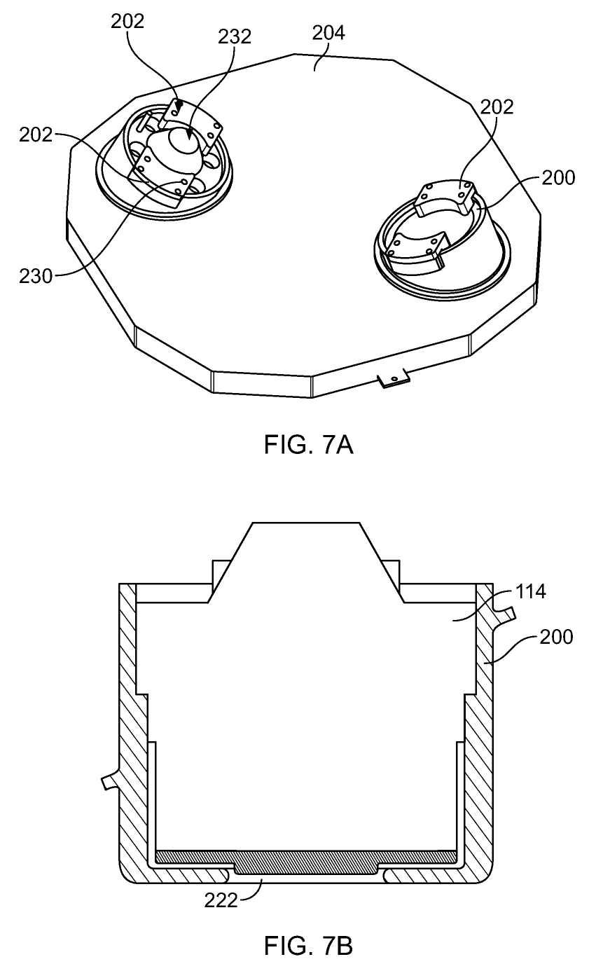

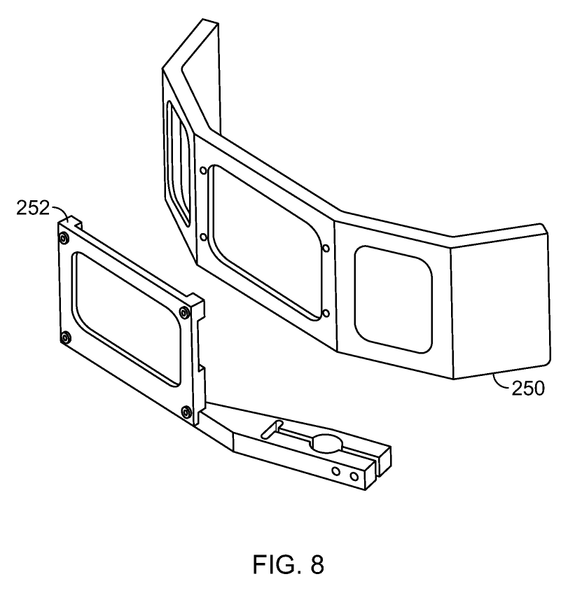

FIG. 7A is a simplified schematic diagram of the lid having integrated gun shields for a dual purpose processing chamber in accordance with one embodiment of the invention. Lid 204 includes integrated gun shields 200. An outer edge of gun shields 200 have gun body retainers 202, which are opposing tabs extending inward to secure body 232 of a process gun. In one embodiment, the arm extension allowing four degrees of freedom and supplying utilities to the process gun of FIG. 3 is affixed to gun body 232.

FIG. 7B illustrates a cross sectional view of the gun shields in accordance with one embodiment of the invention. Gun shield 200 houses process gun 114 having target 222 affixed to a bottom surface of the process gun. In addition, targets composed of different materials may be affixed to different process guns for use during combinatorial processing operations.

FIG. 8 is a simplified schematic of a door shield and door arm for the process kit shield 110 that minimizes particulates in accordance with one embodiment of the invention. Door 250 mates with arm 252 in order to close the opening within the lower shield of the process kit shield.

FIG. 9 is a simplified schematic diagram illustrating an integrated high productivity combinatorial (HPC) system in accordance with one embodiment of the invention. HPC system includes a frame 900 supporting a plurality of processing modules. It should be appreciated that frame 900 may be a unitary frame in accordance with one embodiment. In one embodiment, the environment within frame 900 is controlled. Load lock/factory interface 902 provides access into the plurality of modules of the HPC system. Robot 914 provides for the movement of substrates (and masks) between the modules and for the movement into and out of the load lock 902. Modules 904-912 may be any set of modules and preferably include one or more combinatorial modules. For example, module 904 may be an orientation/degassing module, module 906 may be a clean module, either plasma or non-plasma based, modules 908 and/or 910 may be combinatorial/conventional dual purpose modules as described herein. Module 912 may provide conventional clean or degas as necessary for the experiment design.

Any type of chamber or combination of chambers may be implemented and the description herein is merely illustrative of one possible combination and not meant to limit the potential chamber or processes that can be supported to combine combinatorial processing or combinatorial plus conventional processing of a substrate or wafer. In one embodiment, a centralized controller, i.e., computing device 911, may control the processes of the HPC system. Further details of one possible HPC system are described in U.S. application Ser. Nos. 11/672,478 and 11/672,473. With HPC system, a plurality of methods may be employed to deposit material upon a substrate employing combinatorial processes.

The present invention provides greatly improved methods and apparatus for the combinatorial processing of different regions on a single substrate and processing of full substrate. It is to be understood that the above description is intended to be illustrative and not restrictive. Many embodiments and variations of the invention will become apparent to those of skill in the art upon review of this disclosure. Merely by way of example a wide variety of process times, process temperatures and other process conditions may be utilized, as well as a different ordering of certain processing steps. The scope of the invention should, therefore, be determined not with reference to the above description, but instead should be determined with reference to the appended claims along with the full scope of equivalents to which such claims are entitled.

The embodiments described above provide methods and apparatus for the parallel or rapid serial synthesis, processing and analysis of novel materials having useful properties identified for semiconductor manufacturing processes. Any materials found to possess useful properties can then subsequently be prepared on a larger scale and evaluated in actual processing conditions. These materials can be evaluated along with reaction or processing parameters through the methods described above. In turn, the feedback from the varying of the parameters provides for process optimization. Some reaction parameters which can be varied include, but are not limited to, process material amounts, reactant species, processing temperatures, processing times, processing pressures, processing gas flow rates, processing powers, processing reagent compositions, the rates at which the reactions are quenched, atmospheres in which the processes are conducted, an order in which materials are deposited, etc. In addition, the methods described above enable the processing and testing of more than one material, more than one processing condition, more than one sequence of processing conditions, more than one process sequence integration flow, and combinations thereof, on a single substrate without the need of consuming multiple substrates per material, processing condition, sequence of operations and processes or any of the combinations thereof. This greatly improves the speed as well as reduces the costs associated with the discovery and optimization of semiconductor and other manufacturing operations.

Moreover, the embodiments described herein are directed towards delivering precise amounts of material under precise processing conditions at specific locations of a substrate in order to simulate conventional manufacturing processing operations. As mentioned above, within a region the process conditions are substantially uniform, in contrast to gradient processing techniques which rely on the inherent non-uniformity of the material deposition. That is, the embodiments, described herein locally perform the processing in a conventional manner, e.g., substantially consistent and substantially uniform, while globally over the substrate, the materials, processes and process sequences may vary. It should be noted that the discrete steps of uniform processing is enabled through the HPC systems described herein.

Any of the operations described herein that form part of the invention are useful machine operations. The invention also relates to a device or an apparatus for performing these operations. The apparatus can be specially constructed for the required purpose, or the apparatus can be a general-purpose computer selectively activated or configured by a computer program stored in the computer. In particular, various general-purpose machines can be used with computer programs written in accordance with the teachings herein, or it may be more convenient to construct a more specialized apparatus to perform the required operations.

Although the foregoing invention has been described in some detail for purposes of clarity of understanding, it will be apparent that certain changes and modifications can be practiced within the scope of the appended claims. Accordingly, the present embodiments are to be considered as illustrative and not restrictive, and the invention is not to be limited to the details given herein, but may be modified within the scope and equivalents of the appended claims. In the claims, elements and/or steps do not imply any particular order of operation, unless explicitly stated in the claims.

What is claimed is:

1. A process chamber, comprising:
a lid disposed over a top surface of a processing region of the processing chamber;
a plurality of sputter guns with a target affixed to one end of each of the sputter guns, the plurality of sputter guns extending through the lid of the process chamber, wherein each of the plurality of sputter guns is angled such that a surface of the target affixed to each gun is angled toward an outer periphery of a substrate.

2. The process chamber of claim 1, wherein a normal to the surface of the target is between about 1 degree and about 75 degrees from a normal to a surface of a substrate support of the process chamber and wherein each of the plurality of sputter guns is offset from a center of the substrate support.

3. The process chamber of claim 1, wherein the lid includes a gun shield extending through the lid for each of the plurality of sputter guns, the gun shield supporting corresponding sputter guns.

4. The process chamber of claim 3, wherein each gun shield includes opposing tabs extending inward across a top opening of each gun shield.

5. The process chamber of claim 1, wherein the lid contacts a flange extending along an outer peripheral surface of a sidewall of the process chamber.

6. The process chamber of claim 5, wherein a gap extends between an upper edge of the sidewall and a bottom surface of the lid.

7. The process chamber of claim 3, wherein each gun shield has a bottom surface with an opening defined therethrough, the opening accommodating a target affixed to a bottom surface of the sputter gun, and wherein an outer edge of the bottom surface of the gun shield is rounded and outside a line of sight from the target.

8. A process chamber, comprising;
a lid disposed over a top surface of a processing region of the processing chamber; and
a plurality of sputter guns extending through the lid of the process chamber, each of the plurality of sputter guns is oriented such that a bottom planar surface of each gun is angled toward an outer periphery of a substrate, wherein each of the plurality of sputter guns is affixed to an extension arm, the extension arm configured to enable movement in four degrees of freedom.

9. The process chamber of claim 8, wherein the movement in four degrees of freedom includes movement along an X-axis, a Y-axis, a Z-axis and rotation.

10. The process chamber of claim 8, wherein a normal to the bottom planar surface is between about 1 degree and about 75 degrees from a normal to a surface of a substrate support of the process chamber and wherein each of the plurality of sputter guns is offset from a center of the substrate support.

11. The process chamber of claim 8, further comprising;
a substrate support disposed below the plurality of sputter guns, the substrate support configured to rotate around an axis of the substrate support.

12. The process chamber of claim 11, wherein the extension arm provides utilities to corresponding sputter guns and a shaft located about the axis of the substrate support provides utilities to the substrate support.

13. The process chamber of claim 1, wherein the lid contacts a sidewall of the process chamber on an outer peripheral surface of the sidewall.

14. The process chamber of claim 1, wherein a body of the sputter gun has a ground pathway through the lid and a process shield kit to a lower portion of the chamber body.

15. A method for processing a substrate, comprising:
depositing a layer of material over an entirety of a surface of a substrate through multiple sputter guns disposed above the surface of the substrate; and
combinatorially depositing another layer of material over a region of the layer of material through the multiple sputter guns.

16. The method of claim 15, wherein the depositing and combinatrially depositing are performed sequentially in a same processing chamber.

17. The method of claim 15, wherein the multiple sputter guns are each oriented such that a bottom surface of each sputter gun is angled toward an outer periphery of a process chamber.

18. The method of claim 15, further comprising;
rotating the substrate while depositing the layer of material.

19. The method of claim 15, wherein the combinatorial processing comprises:
depositing material over another region differently than the depositing of another layer, wherein depositing material over another region differently includes one of varying materials, varying process conditions, or varying process sequences.

20. The method of claim 15 further comprising:
moving each of the multiple sputter guns around multiple axes.
